(19) United States
(12) Patent Application Publication
(10) Pub. No.: US 2025/0014931 A1
(43) Pub. Date: Jan. 9, 2025

(54) PROCESS PLATFORM

(71) Applicant: Beijing E-Town Semiconductor Technology Co., Ltd., Beijing (CN)

(72) Inventors: Haiwei LI, Beijing (CN); Changle GUAN, Beijing (CN); Wenbin ZHAO, Beijing (CN); Gonglin LUO, Beijing (CN); Qiang FAN, Beijing (CN)

(21) Appl. No.: 18/761,364

(22) Filed: Jul. 2, 2024

(30) Foreign Application Priority Data
Jul. 7, 2023 (CN) 202310833174.5

(51) Int. Cl. H01L 21/677; H01L 21/67

(52) U.S. Cl. CPC H01L 21/67766; H01L 21/67069; H01L 21/6773; H01L 21/67742; H01L 21/67778

(57) ABSTRACT

Provided is a process platform, relating to the field of semiconductor technologies and specifically. The process platform includes a conveying bin, an accommodating bin, and reaction chambers. The conveying bin is internally provided with a first conveying part having grabbing mechanisms. The accommodating bin is communicated with the conveying bin and used for loading a wafer. The reaction chambers are each communicated with the conveying bin, at least one wafer carrying table is arranged in each reaction chamber, and liftable ejector pins are arranged on a top surface of the wafer carrying table.

### CROSS-REFERENCE TO RELATED APPLICATIONS

The present application claims priority to Chinese Patent Application No. CN202310833174.5, filed with the China National Intellectual Property Administration on Jul. 7, 2023, the disclosure of which is hereby incorporated herein by reference in its entirety.

### TECHNICAL FIELD

The disclosure relates to the field of semiconductor technologies, and more particularly, to a process platform.

### BACKGROUND

On a process platform of a wafer, the prolonged time taken for wafer conveying often impacts the secondary processes within the reaction chamber, thereby delaying the production capacity of the process platform. Consequently, enhancing the efficiency of wafer conveying and, in turn, increasing the productivity of the process platform emerges as a paramount challenge to be addressed.

### SUMMARY

The disclosure provides a process platform, which includes a conveying bin, an accommodating bin and a plurality of reaction chambers.

The conveying bin is internally provided with a first conveying part, the first conveying part being provided with a plurality of grabbing mechanisms.

The accommodating bin is communicated with the conveying bin and is used for loading a wafer.

The plurality of reaction chambers are communicated with the conveying bin, at least one wafer carrying table being arranged in each reaction chamber, liftable ejector pins being arranged on a top surface of wafer carrying table and used for supporting the wafer, and the plurality of grabbing mechanisms being used for conveying the wafer between the plurality of reaction chambers and the accommodating bin.

As disclosed herein, the process platform can carry out process reaction on a plurality of wafers by providing the plurality of reaction chambers and the efficiency of conveying the wafers between the reaction chambers and the accommodating bin can be improved by providing the plurality of grabbing mechanisms, such that the process platform can carry out the process reaction uninterruptedly and the process productivity of the process platform is improved.

It should be understood that the content described herein is not intended to identify critical or essential features of embodiments of the present disclosure, nor is it used to limit the scope of the present disclosure. Other features of the present disclosure will be easily understood through the following description.

### BRIEF DESCRIPTION OF THE DRAWINGS

The above and other features, advantages and aspects of embodiments of the present disclosure will become more apparent with reference to the following detailed description, taken in conjunction with the accompanying drawings. In the drawings, like or similar reference numerals denote like or similar elements, in which:

FIG. 1 is a schematic structural diagram of a process platform according to an embodiment of the disclosure;

FIG. 2 is a schematic structural diagram of a process platform according to an embodiment of the disclosure;

FIG. 3 is a schematic structural diagram of a reaction chamber according to an embodiment of the present disclosure;

FIG. 4 is a schematic structural diagram of a mechanical arm of an embodiment of the present disclosure;

FIG. 5 is a schematic structural diagram of a mechanical arm of an embodiment of the present disclosure;

FIG. 6 is a schematic structural diagram of a mechanical arm of an embodiment of the present disclosure;

FIG. 7 is a schematic structural diagram of a mechanical arm of an embodiment of the present disclosure;

FIG. 8 is a schematic structural diagram of a process platform according to an embodiment of the disclosure;

FIG. 9 is a schematic structural diagram illustrating an application scenario of a process platform according to an embodiment of the present disclosure; and

FIG. 10 is a schematic structural diagram illustrating an application scenario of a process platform according to an embodiment of the present disclosure.

### DETAILED DESCRIPTION

Exemplary embodiments of the disclosure will be described below with reference to the accompanying drawings, in which various details of embodiments of the disclosure are included to assist understanding, and which are to be considered as merely exemplary. Accordingly, it will be recognized by those having ordinary skill in the art that various changes and modifications may be made to the embodiments described herein without departing from the scope of the disclosure. Also, descriptions of well-known functions and constructions are omitted in the following description for clarity and conciseness.

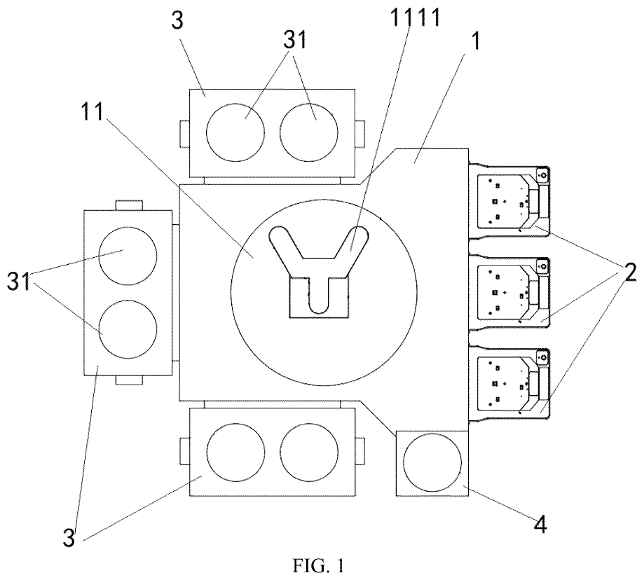

An embodiment of the present disclosure provides a process platform, as shown in FIG. 1, including a conveying bin 1, an accommodating bin 2, and a plurality of reaction chambers 3.

The conveying bin 1 is internally provided with a first conveying part 11, and the first conveying part 11 is provided with a plurality of grabbing mechanisms 1111.

The accommodating bin 2 is communicated with the conveying bin 1 and the accommodating bin 2 is used for loading a wafer.

The plurality of reaction chambers 3 are each communicated with the conveying bin 1, at least one wafer carrying table 31 is arranged in each reaction chamber 3, liftable ejector pins 311 are arranged on a top surface of wafer carrying table 31 for supporting the wafer, and the grabbing mechanisms 1111 are used for conveying the wafer between the reaction chambers 3 and the accommodating bin 2.

According to the embodiment of the present disclosure, it should be noted that:
a conveying port between the accommodating bin 2 and the conveying bin 1 can be designed as a non-closable conveying port, or alternatively the conveying port between the accommodating bin 2 and the conveying bin 1 can be designed as an openable and closable conveying port. When the grabbing mechanism 1111 conveys the wafers between the conveying bin 1 and the accommodating bin 2, the conveying port is opened, so that the accommodating bin 2 is communicated with the conveying bin 1 to facilitate the wafer conveying, and once the grabbing mechanism 1111 has completed the wafer conveying between the conveying bin 1 and the accommodating bin 2, the conveying port is closed.

The conveying port between the reaction chamber 3 and the conveying bin 1 can be designed as a non-closable conveying port, or alternatively the conveying port between the reaction chamber 3 and the conveying bin 1 can be designed as an openable and closable conveying port. When the grabbing mechanism 1111 conveys the wafers between the conveying bin 1 and the reaction chamber 3, the conveying port is opened, so that the reaction chamber 3 is communicated with the conveying bin 1 to facilitate the wafer conveying, and once the grabbing mechanism 1111 has completed the wafer conveying between the conveying bin 1 and the reaction chamber 3, the conveying port is closed.

A lifting state of the ejector pin 311 can be selected and adjusted as required. For example, when a wafer is introduced into the reaction chamber, the ejector pin 311 is protruded from a top surface of the wafer carrying table 31 to a high position to support the wafer, and when the wafer is taken out from the reaction chamber 3, the ejector pin 311 is descended from the high position to a low position to be separated from the wafer.

The plurality of reaction chambers 3 may be used for the same process reaction (i.e., they may be the same type of reaction chamber 3), or may be used for different process reactions (i.e., they may be different types of reaction chambers 3). For example, after a process A is completed in a first reaction chamber 3, the grabbing mechanism 1111 conveys the wafer into a second reaction chamber 3 for a process B.

A shape and size of the conveying bin 1 can be selected and adjusted as required, and are not specifically limited herein. For example, the conveying bin 1 may adopt a chamber with a quadrilateral or polygonal structure.

A shape and size of the accommodating bin 2 can be selected and adjusted as required, and are not specifically limited herein.

A quantity and arrangement position of accommodating bin 2 can be selected and adjusted as required. For example, a plurality of accommodating bins 2 are each arranged on a side of the conveying bin 1, facilitating the conveying of the wafers by the grabbing mechanism 1111.

A quantity and arrangement position of the reaction chambers 3 can be selected and adjusted as required. For example, a plurality of reaction chambers 3 are each arranged on a side of the conveying bin 1, or according to the process needs, a plurality of reaction chambers 3 are arranged on a part of sides of the conveying bin 1, and one reaction chamber 3 is arranged on the other sides of the conveying bin 1.

An arrangement position of the accommodating bin 2 relative to the reaction chamber 3 can be selected and adjusted as required. For example, the accommodating bin 2 is arranged on one side of the conveying bin 1, and the reaction chambers 3 are arranged on the other sides of the conveying bin 1, or the accommodating bin 2 and a portion of the reaction chambers 3 are arranged on one side of the conveying bin 1, and the other portion of the reaction chambers 3 are arranged on the other sides of the conveying bin 1.

Shapes and sizes of the reaction chambers 3 may be selected and adjusted as required, and are not specifically limited herein.

Structure and quantity of the grabbing mechanisms 1111 may be selected and adjusted as required, and are not specifically limited herein. For example, the number of grabbing mechanism 1111 may be one or multiple.

Among the plurality of grabbing mechanisms 1111, the wafer conveying by each grabbing mechanism 1111 may be performed independently, or an association relationship of the wafer conveying of the grabbing mechanisms 1111 may be set.

A shape and size of the wafer carrying table 31 can be selected and adjusted as required, and are not specifically limited herein.

A shape and size of a top surface of the wafer carrying table 31 can be adjusted according to the shape and size of the wafer. For example, when a process reaction is required to be performed on a 12-inch wafer, the top surface of the wafer carrying table 31 can be selected to be not smaller than 12 inches.

A shape and quantity of the ejector pins 311 can be selected and adjusted as required, and are not specifically limited herein as long as the ejector pins 311 can stably support the wafer.

In the same reaction chamber 3, lifting positions of the ejector pins 311 for different wafer carrying tables 31 may be the same or different. For example, the ejector pins 311 of a first wafer carrying table 31 may be positioned at a Height 1, and the ejector pins 311 of a second wafer carrying table 31 may be positioned at a Height 2, and the ejector pins 311 of the same wafer carrying table 31 keep a lifting height consistent.

According to the embodiment of the disclosure, the process platform can carry out process reaction on a plurality of wafers by providing the plurality of reaction chambers 3, and the efficiency of conveying the wafers between the reaction chambers 3 and the accommodating bin 2 can be improved by providing the plurality of grabbing mechanisms 1111, such that the process platform can carry out the process reaction uninterruptedly and the process capacity of the process platform is improved. Because the ejector pin is arranged on the top surface of the wafer carrying table 31 in a liftable manner, the ejector pin can be matched with the grabbing mechanisms 1111 at different positions and heights, so that the grabbing mechanisms 1111 can place the wafer on the wafer carrying table 31 smoothly or take the wafer out of the wafer carrying table 31.

In an example, the plurality of reaction chambers 3 includes at least one type of reaction chamber for wafer stripping, wafer thermal processing, wafer oxidation, or wafer etching.

In an example, the process platform is applied to a wafer stripping process, employing plasma technologies to remove photoresist that is no longer required on the top surface of the wafer. A 12-inch wafer is placed within the reaction chamber 3, where external radio frequency energy, induced by the flow of gases such as oxygen and nitrogen, generates plasma through inductive coupling. This prompts an oxidation reaction between the surface of the wafer and the photoresist, resulting in the formation of volatile compounds such as carbon monoxide, carbon dioxide and water, effectively stripping off the photoresist. In the process platform of the example of the disclosure, the provision of the reaction chambers 3 having a type of photoresist stripping, each equipped with at least one wafer carrying table 31, increases the number of the wafers for the photoresist stripping by the process platform. The inclusion of the mechanical arms improves the efficiency of conveying the wafer, rendering the process platform continuously operational to the maximum extent and significantly boosting the productivity of wafer process.

In an example, two wafer carrying tables 31 are spaced in each reaction chamber 3, with a first conveying part 11 equipped with four grabbing mechanisms 1111. The four grabbing mechanisms 1111 convey wafers between the reaction chamber 3 and the accommodating bin 2. Specifically, the four grabbing mechanisms 1111 take out four wafers from the accommodating bin 2, and convey the four wafers into the two reaction chambers 3 for process reaction, respectively. Through repetitive operations by the four grabbing mechanisms 1111, each reaction chamber 3 has wafers for process reaction. Subsequently, two grabbing mechanisms 1111 of the four grabbing mechanisms 1111 still take out two unprocessed wafers from the accommodating bin 2. When any one of the reaction chambers 3 completes the process reaction, the two idle grabbing mechanisms 1111 seize the processed wafers from the reaction chamber 3. Concurrently, the two grabbing mechanisms 1111 holding unprocessed wafers introduce the two wafers into the reaction chamber 3 for further process reaction, thereby rendering the continuous operations and improving the productivity of the wafer process.

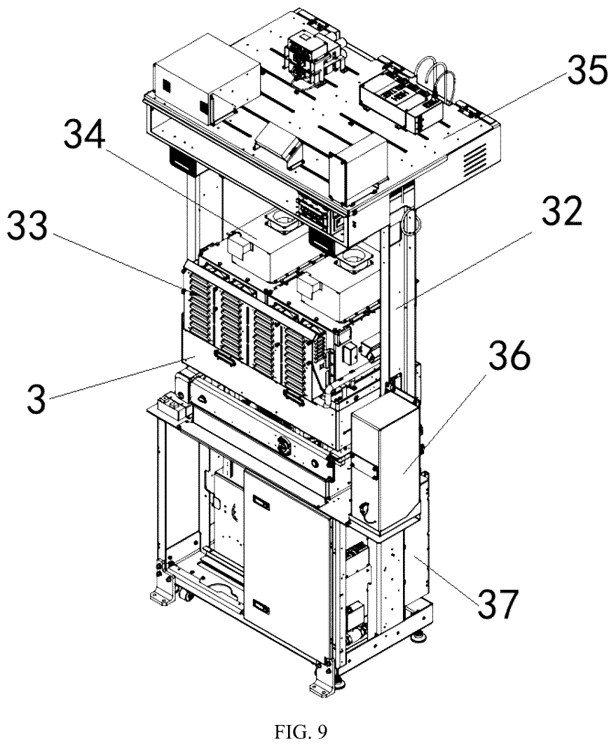

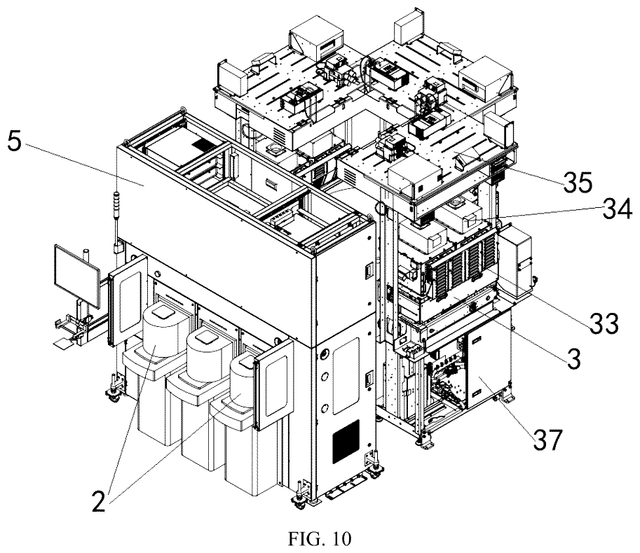

In an example, as shown in FIGS. 9 and 10, the reaction chamber 3 is a modular device for facilitating assembly with the conveying bin 1. The modular device includes a frame 32. The frame 32 is provided with the reaction chamber 3, a plasma source 33, a plasma matching box 34, an electrical module 35, a main control module 36 and a gas supply system 37, wherein the main control module 36 controls the gas supply system 37 to supply a process gas (such as oxygen and nitrogen) to the plasma source 33, the plasma matching box 34 emits radio frequency energy to the process gas to ionize it into a plasma, the plasma enters the reaction chamber 3 to undergo a process reaction with a wafer, and the electrical module 35 is configured to generate a control signal to the reaction chamber 3, the plasma source 33, the plasma matching box 34, the main control module 36 and the gas supply system 37.

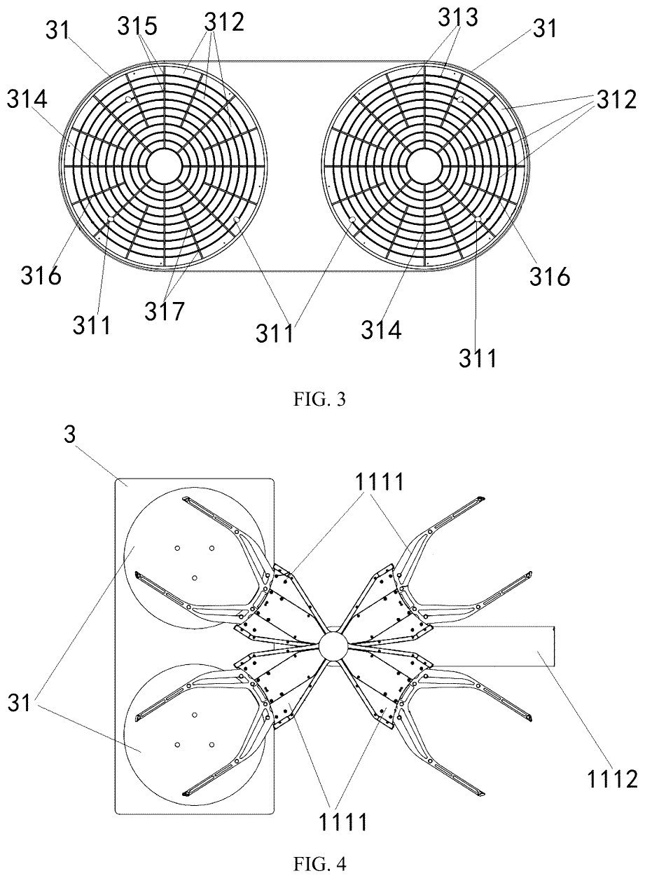

In an embodiment, as shown in FIG. 3, the process platform further includes a heating part 312. The heating part 312 is arranged on the top surface of the wafer carrying table 31 and is used for heating an area of the top surface of the wafer carrying table 31.

According to the embodiment of the present disclosure, it should be noted that:
an arrangement and quantity of the heating part 312 can be selected and adjusted according to the process requirements of the wafer, and are not specifically limited herein. For example, the number of the heating parts 312 is multiple when the wafer is required to be uniformly heated, and the multiple heating parts 312 may be uniformly arranged on the top surface, or when a central area of the wafer is required to be heated higher than an edge area of the wafer, more heating parts 312 are arranged in the central area of the top surface, fewer heating parts 312 are arranged in the edge area of the top surface, or the heating part 312 may be embodied as a whole heating plate arranged on the top surface, and different temperatures may be set in each area of the heating plate.

According to the embodiment of the disclosure, a temperature in the top surface area of the wafer carrying table 31 can be raised by the heating part 312, so that the temperature of the wafer is raised and the efficiency of the process reaction of the wafer is improved. Meanwhile, impurities generated during the process reaction of the wafer can be volatilized by the high temperature, so that the process reaction of the wafer is prevented from being influenced by the impurities and the stability of the process reaction of the wafer is improved.

In an embodiment, as shown in FIG. 3, the process platform further includes a gas delivery part disposed on the top surface of the wafer carrying table 31, the gas delivery part including a plurality of annular gas conduits 313 and a plurality of first strip gas conduits 314. The plurality of annular gas conduits 313 and the plurality of first strip gas conduits 314 are communicated with each other with first exhaust holes 315 provided at communicated positions. The plurality of annular gas conduits 313 are concentrically arranged and are coaxial with the top surface of the wafer carrying table 31. The plurality of first strip gas conduits 314 are uniformly distributed and arranged at an interval along a diameter direction of the top surface of the wafer carrying table 31. The first exhaust holes 315 are communicated with the top surface of the wafer carrying table 31, and are used for outputting process gas.

Herein, the heating part 312 is disposed between two adjacent annular gas conduits 313.

In an embodiment, the process platform further includes a gas delivery part arranged on the top surface of the wafer carrying table 31, the gas delivery part including a plurality of annular gas conduits 313 and a plurality of first strip gas conduits 314. The plurality of annular gas conduits 313 and the plurality of first strip gas conduits 314 are communicated with each other with first exhaust holes 315 provided at communicated positions. The plurality of annular gas conduits 313 are concentrically arranged and are coaxial with the top surface of the wafer carrying table 31. The plurality of first strip gas conduits 314 are uniformly distributed and arranged at an interval along a diameter direction of the top surface of the wafer carrying table 31. The first exhaust holes 315 are communicated with the top surface of the wafer carrying table 31, and are used for outputting process gas.

Herein, the heating part 312 is disposed between two adjacent first strip gas conduits 314.

In an embodiment, the process platform further includes a gas delivery part disposed on the top surface of the wafer carrying table 31, the gas delivery part including a plurality of annular gas conduits 313 and a plurality of first strip gas conduits 314. The plurality of annular gas conduits 313 and the plurality of first strip gas conduits 314 are communicated with each other with first exhaust holes 315 provided at communicated positions. The plurality of annular gas conduits 313 are concentrically arranged and are coaxial with the top surface of the wafer carrying table 31. The plurality of first strip gas conduits 314 are uniformly distributed and arranged at an interval along a diameter direction of the top surface of the wafer carrying table 31. The first exhaust holes 315 are communicated with the top surface of the wafer carrying table 31, and are used for outputting process gas.

Herein, the heating part 312 is disposed between two adjacent annular gas conduits 313 and between two adjacent first strip gas conduits 314.

According to the embodiment of the present disclosure, it should be noted that:
a distance between two adjacent annular gas conduits 313 may be the same or different. In other words, the annular gas conduits 313 may be arranged on the top surface at an equal interval or at non-equal intervals, which is not specifically limited herein.

A shape and size of the first exhaust hole 315 may be selected and adjusted as required, and are not specifically limited herein.

In the process reaction, it is required to raise a temperature of a back surface of the wafer and in turn to increase a temperature of the wafer. However, in view of different process requirements, different areas of the wafer need to be heated to different temperatures. For example, the central area of the wafer needs to be heated to 300° C., the edge area of the wafer needs to be heated to 200° C., and the temperature of the middle area between the edge area and the central area needs to be gradually increased in a curve trend so as to avoid the influence on the process result due to the occurrence of gradient temperature difference. The embodiment of the disclosure can effectively resolve the above problem.

According to the embodiment of the disclosure, by arranging the heating parts 312 between the annular gas conduits 313 and the first strip gas conduits 314, the process gas that has absorbed heat is discharged to the back of the wafer, such that the gradient temperature between two adjacent heating parts 312 is reduced, the wafer is heated uniformly, and the stability of the process result of the wafer is further improved.

In an example, nitrogen can be employed as the process gas within the gas delivery part.

In an embodiment, as shown in FIG. 3, the gas delivery part further includes a plurality of second strip gas conduits 316 communicated with a portion of the annular gas conduits 313 with second exhaust holes 317 provided at communicated positions. The plurality of second strip gas conduits 316 are uniformly distributed and arranged at an interval along a diameter direction of the top surface of the wafer carrying table 31. The plurality of second strip gas conduits 316 and the plurality of first strip gas conduits 314 are arranged in a staggered manner. The second exhaust holes 317 are communicated with the top surface of the wafer carrying table 31, and are used for outputting the process gas.

Herein, the heating part 312 is disposed between two adjacent second strip gas conduits 316.

According to the embodiment of the present disclosure, it should be noted that:
a length of the second strip gas conduit 316 may be selected and adjusted as required. For example, the length of the second strip gas conduit 316 may be the same as the length of the first strip gas conduit 314, or the length of the second strip gas conduit 316 may be less than the length of the first strip gas conduit 314.

An arrangement position of the second strip gas conduits 316 can be selected and adjusted according to the process requirements. For example, when a gradient temperature in a central area of the wafer is required to be high, the second strip gas conduits 316 are arranged at a position close to the central area of the top surface of the wafer carrying table 31, so that a gas displacement in the central area of the top surface of the wafer carrying table 31 is increased and in turn a temperature difference in the central area of the wafer is reduced.

A shape and size of the second exhaust hole 317 may be selected and adjusted as required, and are not specifically limited herein.

According to the embodiment of the disclosure, by arranging the heating parts 312 between two adjacent second strip gas conduits 316, the process gas that has absorbed heat is discharged to the back of the wafer, such that the gradient temperature between two adjacent heating parts 312 is reduced, the wafer is heated uniformly, and the stability of the process result of the wafer is further improved.

In an embodiment, as shown in FIG. 1, the process platform further includes a cooling bin 4, which is arranged on a conveying table and which is used for cooling the wafer after the process reaction.

According to the embodiment of the present disclosure, it should be noted that:
an arrangement position of the cooling bin 4 can be selected and adjusted according to the process requirements. For example, when the wafer to be conveyed into the accommodating bin 2 is a low-temperature wafer, the cooling bin 4 is arranged between the reaction chamber 3 and the accommodating bin 2; as another example, when two adjacent reaction chambers 3 are different types of reaction chambers 3 and the wafer needs to be conveyed between the two adjacent reaction chambers 3 but the temperature requirements are different, the cooling bin 4 is arranged between the two adjacent reaction chambers 3.

A quantity of cooling bins 4 can be selected and adjusted as required, and is not specifically limited herein.

According to the embodiment of the disclosure, by arranging the cooling bin 4 on the conveying table, the processed wafer can be temporarily accommodated therein, preventing the wafer from being cooled in the reaction chamber 3 to delay the next process, thereby further improving the productivity of the reaction chamber 3.

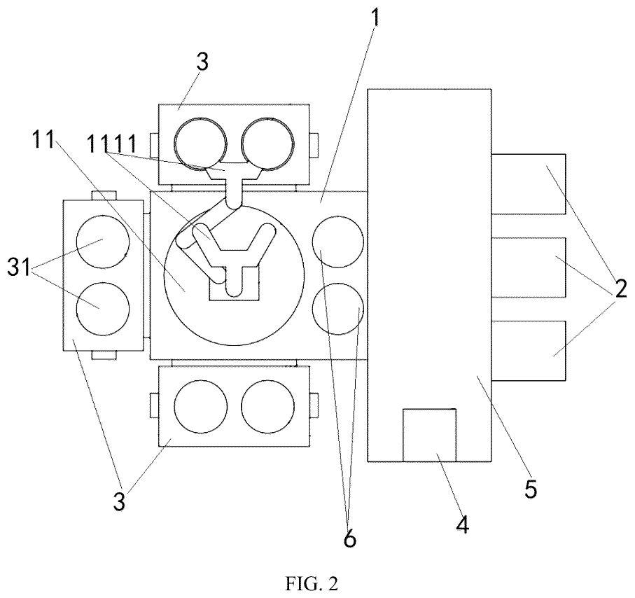

In an example, as shown in FIGS. 2 and 8, the cooling bin 4 may be provided in a front-end module 5.

In an embodiment, as shown in FIGS. 2 and 8, when the plurality of reaction chambers 3 and the conveying bin 1 maintain vacuum environments internally, the process platform further includes:

a front-end module 5 and a first transfer bin 6, wherein the first transfer bin 6 is arranged in the conveying bin 1, the front-end module 5 is arranged between the first transfer bin 6 and the accommodating bin 2, and the front-end module 5 is used for conveying the wafer between the accommodating bin 2 and the first transfer bin 6.

According to the embodiment of the present disclosure, it should be noted that:
the front-end module 5 can be understood as a device for conveying the wafers from the non-vacuum accommodating bin 2 to the vacuum first transfer bin 6, and the specific structure thereof is not limited in detail herein.

A quantity of the first transfer bins 6 may be selected and adjusted as required, and is not specifically limited herein.

According to the embodiment of the disclosure, by arranging the front-end module 5, the influence on the vacuum environments inside the reaction chamber 3 and the conveying bin 1 can be avoided in the wafer conveying process, and in the meanwhile the loss of the process gas and the plasma in the reaction chamber 3 can be reduced, thereby shortening the time for adjusting the internal environment in the reaction chamber 3 during the secondary process reaction and further improving the productivity of the process platform.

In an embodiment, as shown in FIG. 8, the process platform further includes a second conveying part 7 and a second transfer bin 8, wherein the second conveying part 7 and the second transfer bin 8 are both arranged in the conveying bin 1, the second conveying part 7 is arranged between the first conveying part 11 and the accommodating bin 2, the second transfer bin 8 is arranged between the first conveying part 11 and the second conveying part 7, and the second transfer bin 8 is used to temporarily accommodate the wafer conveyed from the second conveying part 7 to the first conveying part 11.

According to the embodiment of the present disclosure, it should be noted that:

Structure and quantity of the grabbing mechanisms 1111 arranged in the second conveying part 7 can be selected and adjusted as required. For example, the structure and the quantity of the grabbing mechanisms 1111 of the second conveying part 7 and the first conveying part 11 are the same. Based on this, the grabbing mechanisms 1111 of the second conveying part 7 can not only transfer the wafers to the second transfer bin 8, but also transfer the wafers to a portion of the reaction chambers 3, thereby improving the transfer efficiency of the wafers.

A quantity of the second transfer bins 8 can be selected and adjusted as required, and is not specifically limited herein.

According to the embodiment of the disclosure, by arranging the second conveying part 7 and the second transfer bin 8, the transfer efficiency of the wafers between the accommodating bin 2 and the reaction chamber 3 can be improved.

In an embodiment, as shown in FIG. 4, the process platform further includes a first mechanical arm 1112, a first end of the first mechanical arm 1112 is connected to the conveying bin 1, a second end of the first mechanical arm 1112 is rotatably connected to the plurality of grabbing mechanisms 1111, and the plurality of grabbing mechanisms 1111 are each arranged at a first height.

Herein, a lifting height of the top end of the ejector pins 311 is adapted to an arranging height of the plurality of grabbing mechanisms 1111.

According to the embodiment of the present disclosure, it should be noted that:
the first mechanical arm 1112 and the grabbing mechanism 1111 jointly constitute a mechanical arm structure.

The lifting height of the top end of the ejector pins 311 is adapted to the arranging height of the plurality of grabbing mechanisms 1111, which can be understood as follows: when the grabbing mechanisms 1111 convey the wafers into the reaction chamber 3, the top of the ejector pins 311 is adjusted to the first height to abut against the wafer.

Operations of the plurality of grabbing mechanisms 1111 specifically proceed as follows:
after a portion of the grabbing mechanisms 1111 takes out the wafers from the reaction chamber 3, the grabbing mechanisms 1111 are rotated to allow the other portion of the grabbing mechanisms 1111 holding the wafers which have not undergone the process reaction to align with the reaction chamber 3, and conveys the wafers which have not undergone the process reaction into the reaction chamber 3.

According to the embodiment of the disclosure, by arranging the rotatable grabbing mechanisms 1111, the wafers which have undergone the process reaction and the wafers which have not undergone the process reaction can be quickly alternated, thereby shortening the time for replacing the wafers during the process reaction and improving the process efficiency.

In an example, when the plurality of reaction chambers 3 and the conveying bin 1 maintain vacuum environments internally, a grabbing end of the grabbing mechanism 1111 may adopt a suction cup for sucking an edge of the wafer.

According to the example of the disclosure, by the arrangement of the suction cup, a transverse friction between the grabbing mechanism 1111 and the wafer can be increased, preventing the wafer from falling off from the grabbing mechanism 1111 in the conveying process.

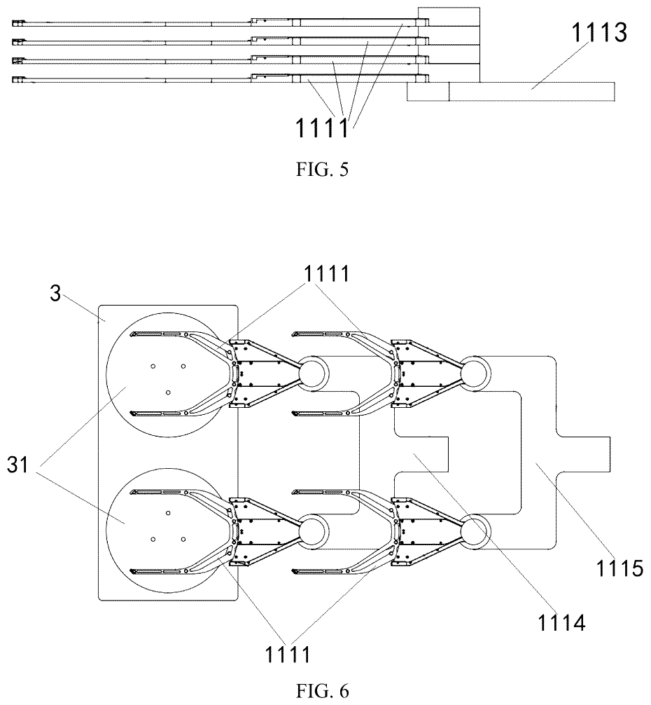

In an embodiment, as shown in FIG. 5, the process platform further includes a second mechanical arm 1113, a first end of the second mechanical arm 1113 is connected to the conveying bin 1, a second end of the second mechanical arm 1113 is rotatably connected to the plurality of grabbing mechanisms 1111, and at least a portion of the plurality of grabbing mechanisms 1111 are arranged at different heights.

Herein, a lifting height of the top end of the ejector pins 311 is adapted to an arranging height of the plurality of grabbing mechanisms 1111.

According to the embodiment of the present disclosure, it should be noted that:
the second mechanical arm 1113 and the grabbing mechanism 1111 jointly constitute a mechanical arm structure.

The arranging height of the plurality of grabbing mechanisms 1111 can be selected and adjusted as required. For example, the plurality of grabbing mechanisms 1111 can be arranged at different heights, respectively, or a portion of grabbing mechanisms 1111 can be arranged at the same height, and the other portion of grabbing mechanisms 1111 can be arranged at different heights, respectively.

The lifting height of the top end of the ejector pins 311 is adapted to the arranging height of the plurality of grabbing mechanisms 1111, which can be understood as follows: when grabbing mechanisms 1111 at a higher position convey or remove the wafers into or from a first wafer carrying table 31 of the reaction chamber 3, the ejector pins 311 of the first wafer carrying table 31 are adjusted to the higher position of the grabbing mechanism 1111. When grabbing mechanisms 1111 at a lower position convey or remove the wafers into or from the first wafer carrying table 31, the ejector pins 311 are adjusted from the higher position to the lower position. That is, the height of the ejector pins 311 of any one wafer carrying table 31 is adjusted according to the height of the grabbing mechanisms 1111 for conveying the wafers to the wafer carrying table 31.

According to the embodiment of the disclosure, by arranging the grabbing mechanisms 1111 at different heights, the space occupied by the grabbing mechanisms 1111 during the rotation can be reduced and the lifting of ejector pins 311 is adapted to the height of the grabbing mechanisms 1111, thereby preventing excessive lifting time taken by grabbing mechanisms 1111 from impacting the efficiency of wafer replacement.

In an example, the second mechanical arm 1113 is provided with four grabbing mechanisms 1111, the four grabbing mechanisms 1111 are positioned at different heights, and two wafer carrying tables 31 are disposed in the reaction chamber 3. The operations specifically proceed as follows: the four grabbing mechanisms 1111 rotate to the same direction, four wafers can be taken out at the same time during the removal of the wafer from the first transfer bin 6 (or the accommodating bin 2), then the four grabbing mechanisms 1111 rotate to different angles, and when the first grabbing mechanism 1111 introduces a wafer to the first wafer carrying table 31 of the first reaction chamber 3 and the second grabbing mechanism 1111 introduces a wafer to the second wafer carrying table 31 of the first reaction chamber 3, the ejector pins 311 of the first wafer carrying table 31 are adjusted to a height 1 and the ejector pins 311 of the second wafer carrying table 31 are adjusted to a height 2. With the completion of the process reaction, when the second grabbing mechanism 1111 takes out the wafer from the first wafer carrying table 31 and the first grabbing mechanism 1111 takes out the wafer from the second wafer carrying table 31, the ejector pins 311 of the first wafer carrying table 31 are adjusted to the height 2 and the ejector pins 311 of the second wafer carrying table 31 are adjusted to the height 1. With the completion of the process reaction, when the third grabbing mechanism 1111 takes out the wafer from the first wafer carrying table 31 and the fourth grabbing mechanism 1111 takes out the wafer from the second wafer carrying table 31, the ejector pins 311 of the first wafer carrying table 31 are adjusted to a height 3 and the ejector pins 311 of the second wafer carrying table 31 are adjusted to a height 4. With the completion of the process reaction, when the fourth grabbing mechanism 1111 takes out the wafer from the first wafer carrying table 31 and the third grabbing mechanism 1111 takes out the wafer from the second wafer carrying table 31, the ejector pins 311 of the first wafer carrying table 31 are adjusted to the height 4 and the ejector pins 311 of the second wafer carrying table 31 are adjusted to the height 3.

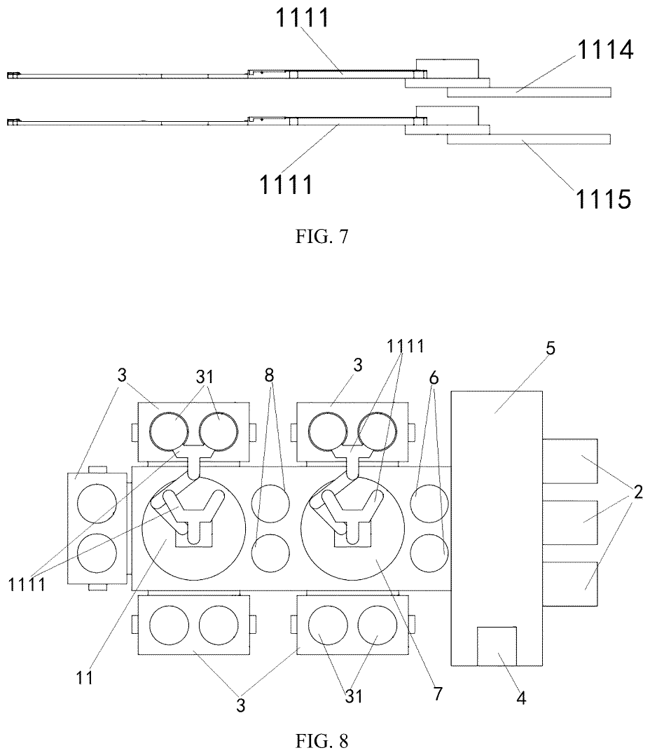

In an embodiment, as shown in FIGS. 6 and 7, the process platform further includes a third mechanical arm 1114 and a fourth mechanical arm 1115, a first end of the third mechanical arm 1114 is connected to the conveying bin 1, a second end of the third mechanical arm 1114 is connected to a portion of the plurality of grabbing mechanisms 1111, a first end of the fourth mechanical arm 1115 is connected to the conveying bin 1, a second end of the fourth mechanical arm 1115 is connected to the other portion of the plurality of grabbing mechanisms 1111, the portion of the grabbing mechanisms 1111 is arranged at a first height, and the other portion of grabbing mechanisms 1111 is arranged at a second height.

Herein, a lifting height of the top end of the ejector pins 311 is adapted to arranging heights of the portion of the grabbing mechanisms 1111 and the other portion of the grabbing mechanisms 1111.

According to the embodiment of the present disclosure, it should be noted that:
the third mechanical arm 1114 and the grabbing mechanism 1111 jointly constitute a mechanical arm structure;
the fourth mechanical arm 1115 and the grabbing mechanism 1111 jointly constitute a mechanical arm structure.

The lifting height of the top end of the ejector pins 311 is adapted to the arranging height of the plurality of grabbing mechanisms 1111, which can be understood as follows: when the grabbing mechanism 1111 at the first height convey or remove the wafers into or from the wafer carrying table 31 of the reaction chamber 3, the ejector pins 311 of the wafer carrying table 31 are adjusted to the first height of the grabbing mechanism 1111. When the grabbing mechanisms 1111 at the second height convey or remove the wafers into or from the wafer carrying table 31, the ejector pins 311 are adjusted from the first height to the second height. That is, the height of the ejector pins 311 of the wafer carrying table 31 can be adjusted according to the height of the grabbing mechanism 1111 for conveying the wafers to the wafer carrying table 31.

According to the embodiment of the disclosure, the lifting of ejector pins 311 is adapted to the height of the grabbing mechanisms 1111, thereby preventing excessive lifting time taken by grabbing mechanisms 1111 from impacting the efficiency of wafer replacement.

In an example, the third mechanical arm 1114 is provided with two grabbing mechanisms 1111, which are the first grabbing mechanism 1111 and the second grabbing mechanism 1111, respectively, and the fourth mechanical arm 1115 is provided with two grabbing mechanisms 1111, which are the third grabbing mechanism 1111 and the fourth grabbing mechanism 1111, wherein the first grabbing mechanism 1111 and the second grabbing mechanism 1111 are positioned at the height 1 (the first height), the third grabbing mechanism 1111 and the fourth grabbing mechanism 1111 are positioned at the height 2 (the second height), two wafer carrying tables 31 are arranged in the reaction chamber 3, and the operations proceed as follows: when the first grabbing mechanism 1111 and the second grabbing mechanism introduce the wafers to the two wafer carrying tables 31, the ejector pins 311 of the two wafer carrying tables 31 are adjusted to have the height 1. With the completion of the process reaction, when the third grabbing mechanism 1111 and the fourth grabbing mechanism 1111 take out the wafers from the two wafer carrying tables 31, the ejector pins 311 of the two wafer carrying tables 31 are adjusted to the height 2. After the third grabbing mechanism 1111 and the fourth grabbing mechanism 1111 take out the wafers, the first grabbing mechanism 1111 and the second grabbing mechanism 1111 introduce the wafers which have not completed the process reaction and which are grabbed from the accommodating bin 2 into the two wafer carrying tables 31, and the ejector pins of the two wafer carrying tables 31 are adjusted to the height 1 again, so that the process can be carried out uninterrupted and the process capacity is improved.

In the description of the specification, it is to be understood that orientations and positional relationships indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, and the like, are based on the orientations and positional relationships shown in the drawings, and are used merely for convenience of description and simplicity of description, but do not indicate or imply that the device or element referred to must have a particular orientation, be constructed and operated in a particular orientation, and therefore should not be considered as limiting the present disclosure.

Furthermore, the terms “first” and “second” and “first” are used for descriptive purposes only and are not to be construed as indicating or implying relative importance or to implicitly indicate the number of technical features indicated. Thus, a feature defined as “first” or “second” may explicitly or implicitly include one or more that feature. In the description of the present disclosure, “a plurality” means two or more unless specifically limited otherwise.

In the present disclosure, unless explicitly stated or limited otherwise, the terms “mounted”, “connected”, “attached” and “secured” and the like are construed in the broad sense, e.g., as the meaning of “fixedly connected”, “detachably connected”, or “integral”; the connection can be mechanical connection, electrical connection or communication; the connection can be directly connected or indirectly connected through intervening media, or can be connected through the use of two elements or the interaction of two elements. The specific meaning of the above terms in the present disclosure can be understood based upon a specific case by a person of ordinary skill in the art.

In the present disclosure, unless explicitly stated or limited otherwise, a first feature “on” or “under” a second feature may include a meaning of the first and second features being in direct contact, and may also include the meaning that the first and second features are not in direct contact, but are in contact via another feature between them. Also, the first feature “on”, “above” and “over” the second feature may include a meaning of the first feature being directly above and obliquely above the second feature, or simply indicate that the first feature is at a higher level than the second feature. The first feature “below”, “under” and “beneath” the second feature may include the first feature being directly beneath and obliquely beneath the second feature, or simply indicate that the first feature is at a lower level than the second feature.

The above disclosure provides many different embodiments, or examples, for implementing different features of the disclosure. In order to simplify the disclosure of the present disclosure, the components and arrangements in the specific examples are described above. Of course, they are merely examples and are not intended to restrict the present disclosure. Moreover, the present disclosure may repeat reference numerals and/or reference letters in the various examples for purposes of simplicity and clarity and do not in themselves indicate a relationship between the various embodiments and/or arrangements as discussed.

The above detailed description should not be construed as limiting the scope of the disclosure. It should be understood by those skilled in the art that various modifications, combinations, sub-combinations and substitutions may be made, depending on design requirements and other factors. Any modification, equivalent replacement, and improvement made within the principle of the present disclosure should be included in the protection scope of the present disclosure.

What is claimed is:

1. A process platform, comprising:
a conveying bin internally provided with a first conveying part, the first conveying part being provided with a plurality of grabbing mechanisms;
an accommodating bin communicated with the conveying bin and used for loading a wafer;
a plurality of reaction chambers each communicated with the conveying bin, at least one wafer carrying table being arranged in each reaction chamber, liftable ejector pins being arranged on a top surface of wafer carrying table and used for supporting the wafer, and the plurality of grabbing mechanisms being used for conveying the wafer between the plurality of reaction chambers and the accommodating bin.

2. The process platform of claim 1, further comprising:
a heating part arranged on the top surface of the wafer carrying table and used for heating an area of the top surface of the wafer carrying table.

3. The process platform of claim 2, further comprising:
a gas delivery part arranged on the top surface of the wafer carrying table, the gas delivery part including a plurality of annular gas conduits and a plurality of first strip gas conduits; the plurality of annular gas conduits and the plurality of first strip gas conduits being communicated with each other with first exhaust holes provided at communicated positions, the plurality of annular gas conduits being concentrically arranged and being coaxial with the top surface of the wafer carrying table, the plurality of first strip gas conduits being uniformly distributed and arranged at an interval along a diameter direction of the top surface of the wafer carrying table, and the first exhaust holes being communicated with the top surface of the wafer carrying table and used for outputting process gas;
wherein the heating part is disposed between two adjacent annular gas conduits, and/or the heating part is arranged between two adjacent first strip gas conduits.

4. The process platform of claim 3, wherein the gas delivery part further comprises a plurality of second strip gas conduits communicated with a portion of the annular gas conduits with second exhaust holes provided at communicated positions, the plurality of second strip gas conduits being uniformly distributed and arranged at an interval along a diameter direction of the top surface of the wafer carrying table, the plurality of second strip gas conduits and the plurality of first strip gas conduits being arranged in a staggered manner, and the second exhaust holes being communicated with the top surface of the wafer carrying table and used for outputting the process gas;
wherein the heating part is disposed between two adjacent second strip gas conduits.

5. The process platform of claim 1, further comprising:
a cooling bin is arranged on a conveying table and used for cooling the wafer after the process reaction.

6. The process platform of claim 1, wherein when the plurality of reaction chambers and the conveying bin maintain vacuum environments internally, the process platform further comprises:
a front-end module and a first transfer bin, the first transfer bin being arranged in the conveying bin, the front-end module being arranged between the first transfer bin and the accommodating bin, and the front-end module being used for conveying the wafer between the accommodating bin and the first transfer bin.

7. The process platform of claim 1, further comprising:
a second conveying part and a second transfer bin, the second conveying part and the second transfer bin being both arranged in the conveying bin, the second conveying part being arranged between the first conveying part and the accommodating bin, the second transfer bin being arranged between the first conveying part and the second conveying part, and the second transfer bin being used to temporarily accommodate the wafer conveyed from the second conveying part to the first conveying part.

8. The process platform of claim 1, further comprising a first mechanical arm, a first end of the first mechanical arm being connected to the conveying bin, a second end of the first mechanical arm being rotatably connected to the plurality of grabbing mechanisms, and the plurality of grabbing mechanisms being each arranged at a first height;
wherein a lifting height of the top end of the ejector pins is adapted to an arranging height of the plurality of grabbing mechanisms.

9. The process platform of claim 2, further comprising a first mechanical arm, a first end of the first mechanical arm being connected to the conveying bin, a second end of the first mechanical arm being rotatably connected to the plurality of grabbing mechanisms, and the plurality of grabbing mechanisms being each arranged at a first height;
wherein a lifting height of the top end of the ejector pins is adapted to an arranging height of the plurality of grabbing mechanisms.

10. The process platform of claim 3, further comprising a first mechanical arm, a first end of the first mechanical arm being connected to the conveying bin, a second end of the first mechanical arm being rotatably connected to the plurality of grabbing mechanisms, and the plurality of grabbing mechanisms being each arranged at a first height;
wherein a lifting height of the top end of the ejector pins is adapted to an arranging height of the plurality of grabbing mechanisms.

11. The process platform of claim 4, further comprising a first mechanical arm, a first end of the first mechanical arm being connected to the conveying bin, a second end of the first mechanical arm being rotatably connected to the plurality of grabbing mechanisms, and the plurality of grabbing mechanisms being each arranged at a first height;
wherein a lifting height of the top end of the ejector pins is adapted to an arranging height of the plurality of grabbing mechanisms.

12. The process platform of claim 5, further comprising a first mechanical arm, a first end of the first mechanical arm being connected to the conveying bin, a second end of the first mechanical arm being rotatably connected to the plurality of grabbing mechanisms, and the plurality of grabbing mechanisms being each arranged at a first height;
wherein a lifting height of the top end of the ejector pins is adapted to an arranging height of the plurality of grabbing mechanisms.

13. The process platform of claim 6, further comprising a first mechanical arm, a first end of the first mechanical arm being connected to the conveying bin, a second end of the first mechanical arm being rotatably connected to the plurality of grabbing mechanisms, and the plurality of grabbing mechanisms being each arranged at a first height;
wherein a lifting height of the top end of the ejector pins is adapted to an arranging height of the plurality of grabbing mechanisms.

14. The process platform of claim 7, further comprising a first mechanical arm, a first end of the first mechanical arm being connected to the conveying bin, a second end of the first mechanical arm being rotatably connected to the plurality of grabbing mechanisms, and the plurality of grabbing mechanisms being each arranged at a first height;
wherein a lifting height of the top end of the ejector pins is adapted to an arranging height of the plurality of grabbing mechanisms.

15. The process platform of claim 1, further comprising a second mechanical arm, a first end of the second mechanical arm being connected to the conveying bin, a second end of the second mechanical arm being rotatably connected to the plurality of grabbing mechanisms, and at least a portion of the plurality of grabbing mechanisms being arranged at different heights;
wherein a lifting height of the top end of the ejector pins is adapted to an arranging height of the plurality of grabbing mechanisms.

16. The process platform of claim 2, further comprising a second mechanical arm, a first end of the second mechanical arm being connected to the conveying bin, a second end of the second mechanical arm being rotatably connected to the plurality of grabbing mechanisms, and at least a portion of the plurality of grabbing mechanisms being arranged at different heights;
wherein a lifting height of the top end of the ejector pins is adapted to an arranging height of the plurality of grabbing mechanisms.

17. The process platform of claim 3, further comprising a second mechanical arm, a first end of the second mechanical arm being connected to the conveying bin, a second end of the second mechanical arm being rotatably connected to the plurality of grabbing mechanisms, and at least a portion of the plurality of grabbing mechanisms being arranged at different heights;
wherein a lifting height of the top end of the ejector pins is adapted to an arranging height of the plurality of grabbing mechanisms.

18. The process platform of claim 4, further comprising a second mechanical arm, a first end of the second mechanical arm being connected to the conveying bin, a second end of the second mechanical arm being rotatably connected to the plurality of grabbing mechanisms, and at least a portion of the plurality of grabbing mechanisms being arranged at different heights;
wherein a lifting height of the top end of the ejector pins is adapted to an arranging height of the plurality of grabbing mechanisms.

19. The process platform of claim 5, further comprising a second mechanical arm, a first end of the second mechanical arm being connected to the conveying bin, a second end of the second mechanical arm being rotatably connected to the plurality of grabbing mechanisms, and at least a portion of the plurality of grabbing mechanisms being arranged at different heights;
wherein a lifting height of the top end of the ejector pins is adapted to an arranging height of the plurality of grabbing mechanisms.

20. The process platform of claim 1, further comprising a third mechanical arm and a fourth mechanical arm, a first end of the third mechanical arm being connected to the conveying bin, a second end of the third mechanical arm being connected to a portion of the plurality of grabbing mechanisms, a first end of the fourth mechanical arm being connected to the conveying bin, a second end of the fourth mechanical arm being connected to the other portion of the plurality of grabbing mechanisms, the portion of the grabbing mechanisms being arranged at a first height, and the other portion of grabbing mechanisms is arranged at a second height;
wherein a lifting height of the top end of the ejector pins is adapted to arranging heights of the portion of the grabbing mechanisms and the other portion of the grabbing mechanisms.
